(19) United States
(12) Patent Application Publication
(10) Pub. No.: US 2023/0361139 A1
(43) Pub. Date: Nov. 9, 2023

(54) EDGE SEALS FOR SEMICONDUCTOR DEVICES

(71) Applicant: SEMICONDUCTOR COMPONENTS INDUSTRIES, LLC, Scottsdale, AZ (US)

(72) Inventors: Swarnal BORTHAKUR, Boise, ID (US); Jeffrey Peter GAMBINO, Gresham, OR (US)

(73) Assignee: SEMICONDUCTOR COMPONENTS INDUSTRIES, LLC, Scottsdale, AZ (US)

(21) Appl. No.: 18/185,548

(22) Filed: Mar. 17, 2023

Related U.S. Application Data
(60) Provisional application No. 63/364,400, filed on May 9, 2022.

(51) Int. Cl. H01L 27/146

(52) U.S. Cl. CPC H01L 27/14618; H01L 27/14636; H01L 27/14623; H01L 27/14632; H01L 27/14687; H01L 27/14685

(57) ABSTRACT

Implementations of a semiconductor device may include a first semiconductor die hybrid bonded to a second semiconductor die; a bond pad included in the second semiconductor die; a through-silicon-via (TSV) extending entirely through the first semiconductor die and to the bond pad included in the second semiconductor die; and a trench formed entirely through the first semiconductor die and to the bond pad included in the second semiconductor die. The trench may form an edge seal.

### CROSS REFERENCE TO RELATED APPLICATIONS

This document claims the benefit of the filing date of U.S. Provisional Patent Application 63/364,400, entitled “Edge Seals for Semiconductor Packages” to Gambino et al. which was filed on May 9, 2022, the disclosure of which is hereby incorporated entirely herein by reference.

### BACKGROUND

### 1. Technical Field

Aspects of this document relate generally to semiconductor devices. More specific implementations involve image sensor semiconductor devices.

### 2. Background

Image sensor devices include regions referred to as pixels that are sensitive to various wavelengths of electromagnetic radiation. Image sensor devices read out electrical signals from the pixels for further image processing.

### SUMMARY

Implementations of a semiconductor device may include a first semiconductor die hybrid bonded to a second semiconductor die; a bond pad included in the second semiconductor die; a through-silicon-via (TSV) extending entirely through the first semiconductor die and to the bond pad included in the second semiconductor die; and a trench formed entirely through the first semiconductor die and to the bond pad included in the second semiconductor die. The trench may form an edge seal.

Implementations of a semiconductor device may include one, all, or any of the following:

The trench may surround the TSV and the bond pad.

The semiconductor device may include a tungsten grid at least partially overlapping the trench.

The nitride material may fill the trench.

The semiconductor device may include a light block material included in the trench.

The light block layer may extend over a first side of the first semiconductor die.

The semiconductor device may include a nitride layer coupled over a plurality of sidewalls of the TSV and an encapsulant coupled over sidewalls of the nitride layer.

The trench may be present on at least two sides of the TSV.

Implementations of a method of forming a semiconductor device may include hybrid bonding a first semiconductor die to a second semiconductor die; forming a through-silicon-via (TSV) extending entirely through a thickness of the first semiconductor die and to a bond pad included in the second semiconductor die; and simultaneously forming a trench entirely through the thickness of the first semiconductor die and into the second semiconductor die. The trench may extend into the second die to a same depth into a thickness of the second semiconductor die as a depth the TSV extends into the thickness of the second semiconductor die. The trench may form an edge seal.

Implementations of a method of forming a semiconductor device may include one, all, or any of the following:

The method may include singulating the first semiconductor die and the second semiconductor die and where simultaneously forming a trench further may include forming the trench between an outer edge of the semiconductor device and a second edge seal formed in the thickness of the first semiconductor die.

Simultaneously forming a trench further may include forming the trench between the TSV and a second edge seal formed in the thickness of the first semiconductor die.

The method may include forming a silicon nitride layer on sidewalls of the trench.

The method may include applying an encapsulant to sidewalls of the trench and sidewalls of the TSV.

The method may include forming a light block layer on sidewalls of the trench and forming a silicon nitride layer on the sidewalls of the trench.

Implementations of a method of forming a semiconductor device may include hybrid bonding a first semiconductor die to a second semiconductor die; forming a trench entirely through a thickness of the first semiconductor die and into the second semiconductor die where the trench extends into the second die to a first depth. The method may also include, after forming the trench, forming a through-silicon-via (TSV) extending entirely through a thickness of the first semiconductor die and to a bond pad included in the second semiconductor die at the first depth. The trench may form an edge seal.

Implementations of a method of forming a semiconductor device may include one, all, or any of the following:

The method may include singulating the first semiconductor die and the second semiconductor die and where forming the trench further may include forming the trench between an outer edge of the semiconductor device and a second edge seal formed in the thickness of the first semiconductor die.

Forming the TSV further may include forming the TSV so the trench may be between the TSV and a second edge seal formed in the thickness of the first semiconductor die.

The method may include filling the trench with silicon nitride.

The method may include forming a light block layer on sidewalls of the trench and forming a silicon nitride layer on the sidewalls of the trench.

The method may include filling the trench with silicon dioxide.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross sectional view of an implementation of a stacked image sensor;

FIG. 2 is a cross sectional view of another implementation of a stacked image sensor;

FIG. 3 is a cross sectional view of another implementation of a stacked image sensor;

FIG. 4 is a cross sectional view of another implementation of a stacked image sensor;

FIG. 5 is a cross sectional view of another implementation of a stacked image sensor;

FIG. 6 is a cross sectional view of another implementation of a stacked image sensor;

FIG. 7 is a top view of the implementation of the stacked image sensor of FIG. 6;

FIG. 8 is a cross sectional view of another implementation of a stacked image sensor;

FIG. 9 is a cross sectional view of another implementation of a stacked image sensor; and

FIG. 10 is a cross sectional view of another implementation of a stacked image sensor.

### DESCRIPTION

This disclosure, its aspects and implementations, are not limited to the specific components, assembly procedures or method elements disclosed herein. Many additional components, assembly procedures and/or method elements known in the art consistent with the intended edge seals for semiconductor devices will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such edge seals for semiconductor devices, and implementing components and methods, consistent with the intended operation and methods.

Implementations of the semiconductor devices disclosed herein relate to semiconductor devices having edge seals. Particular implementations include edge seals used with hybrid bonded stacked semiconductor devices and silicon photomultiplier semiconductor devices. However, the principles disclosed herein may be applied to many other semiconductor device types to form other edge seal implementations.

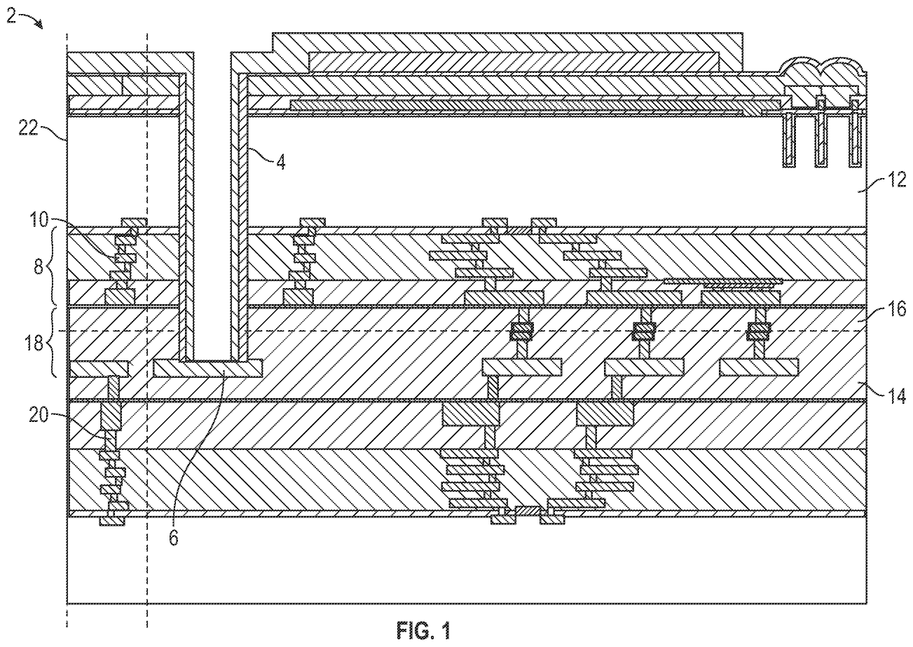

Referring to FIG. 1, a cross-sectional side view of a semiconductor device 2 is illustrated. In various implementations, and as illustrated by FIG. 1, the semiconductor device 2 may be a hybrid bonded stacked image sensor device. In other implementations, the semiconductor device may be a semiconductor device that is not hybrid bonded, not stacked, or not an image sensor device.

As illustrated in FIG. 1, the semiconductor device 2 includes a through-silicon-via (TSV) 4 extending through the first die of the semiconductor device and into the second die of the semiconductor device. While the use of the term “through-silicon-via” is employed to describe openings that pass entirely through or into a significant portion of a semiconductor die, such structures may be formed by passing through various layers other than silicon or through semiconductor substrates other than silicon, such as, by non-limiting example, silicon carbide, gallium arsenide, sapphire, ruby, silicon-on-insulator, or any other semiconductor material type. Accordingly, as used herein, the term “through-silicon-via” also includes those openings that pass through oxides, nitrides, barrier layers, polyimides as well as any of the foregoing semiconductor substrate types. As illustrated by FIG. 1, the TSV extends to bond pad 6 and will, following filling or layering of the sidewalls of the TSV with an electrically conductive material, enable an electrical connection to be established through the TSV and to the bond pad. In various implementations, a bond wire is attached to the top surface of the TSV following filling or layering with the electrically conductive material to establish the electrical connection.

Still referring to FIG. 1, the semiconductor device 2 may include an edge seal region 8 including an edge seal 10. In various implementations, the edge seal 10 includes a plurality of stacked metal layers coupled together through vias. In various implementations, the edge seal 10 is formed in the first semiconductor die/die 12. As illustrated by FIG. 1, in various implementations, the edge seal 10 does not extend across a hybrid bond 16 indicated by the dotted line in FIG. 1 used to bond the first die 12 to the second semiconductor die/die 14. In such implementations, a gap 18 between the edge seal 10 of the first die 12 and an edge seal 20 of the second die 14 is present exists across the hybrid bond 16. In implementations including such a gap 18, cracks may propagate from the outer sidewall 22 of the semiconductor device 2, through the gap 18, past the edge seals 10, 20, and towards the bond pad 6. Such cracks may result during dicing or singulation of the semiconductor device 2. The cracks may result in decreased reliability of the semiconductor device 2, particularly with the electrical connection/joint formed between the TSV 4 and to the bond pad 6. Similarly, in various implementations, moisture may propagate from the outer sidewall of the semiconductor device, through the gap, past the edge seal, and towards the bond pad. The moisture may result in corrosion of the material of the bond pad itself and/or metal connections to the bond pad being corroded, weakened, or otherwise compromised.

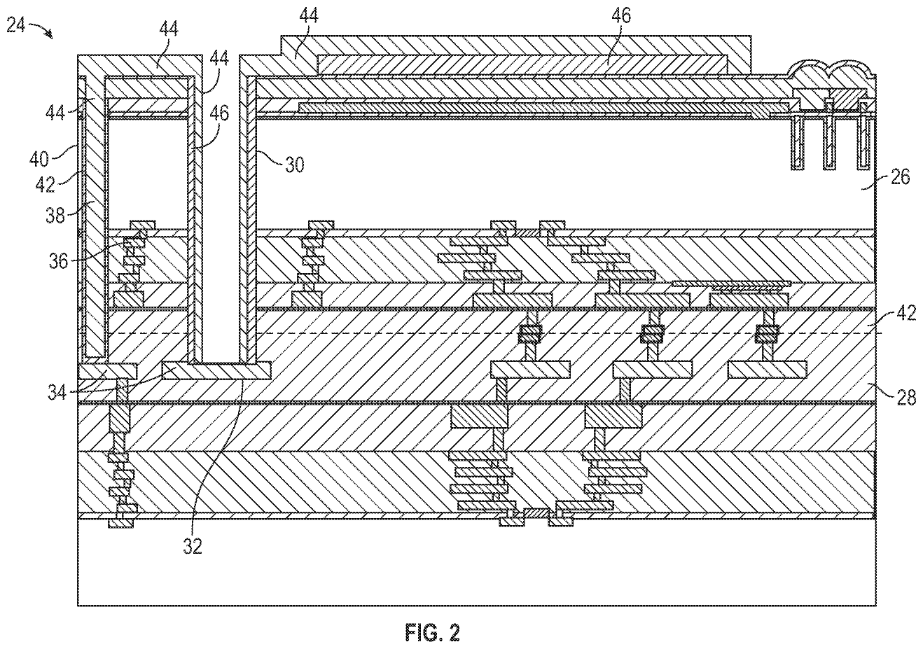

Referring to FIG. 2, a cross-sectional side view of a second implementation of a semiconductor device 24 is illustrated. The semiconductor device of FIG. 2 may be any type of semiconductor device disclosed herein. As illustrated by FIG. 2, the semiconductor device includes a first die 26 and a second die 28. In various implementations the first die 26 may include an image sensor, including any image sensor disclosed herein. In particular implementations, the first die 26 may include a contact image sensor, a CMOS image sensor, and/or a backside illuminated (BSI) image sensor. In other implementations, the first die 26 may include a different type of image sensor. In still other implementations, the first die 26 may not include an image sensor.

In various implementations, the semiconductor device 24 includes second die 28 stacked under the first die 26. In particular implementations the second semiconductor die may include an application specific integrated circuit (ASIC) used for processing electrical signals from the first die 26. In other implementations, the second die may be a non-ASIC die like a memory, microprocessor, digital signal processor, or any other semiconductor device type.

In various implementations, and as illustrated by FIG. 2, the first die 26 is directly coupled to the second die 28. In such implementations, the first die 26 is hybrid bonded to the second die. In other implementations, the first die may be indirectly coupled to the second die or may be bonded to the second die through a bond other than a hybrid bond.

Still referring to FIG. 2, the semiconductor device includes TSV 30. The TSV 30 extends entirely through the material/thickness of the first die 26 and into the material/thickness of the second die 28. In such implementations, the TSV extends to a bond pad 32 within the material/thickness of the second die 28. The bond pad 30 may be a part of a first metal layer 34 within the second die 28 through the metal layer may be a second, third, or greater number of layers in various implementations. The metal layer 34 may include, by non-limiting example, aluminum, copper, any other metal, any type of alloy, or any combination thereof.

In various implementations, as illustrated in FIG. 2, the semiconductor device 24 may include a first edge seal 36. The first edge seal 36, as illustrated, includes a plurality of stacked metal layers coupled together through a plurality of vias. In various implementations, the first edge seal 36 is entirely contained within the material/thickness of the first die 26.

As illustrated in FIG. 2, the semiconductor device 24 includes a second edge seal 38. The second edge seal 38 of FIG. 2 is located between the first edge seal 36 and an outer sidewall 40 of the semiconductor device 24. As illustrated by FIG. 2, in various implementations, the second edge seal 38 extends to a same depth within a thickness of the semiconductor device 24 as the TSV 30 across the full thickness of the first die 26 and into the thickness of the second die 28. In other implementations, the second edge seal 38 may extend within the semiconductor device to a greater depth or lesser depth than the TSV 30. In particular implementations, the second edge seal 38 extends to the first metal layer 34 within the second die and across the hybrid bond 42 interface. In other implementations the second edge seal 38 may extend across the hybrid bond 42 interface between the first and second die but may not necessarily extend to the first metal layer of the second die.

In various implementations, the second edge seal 38 is/includes a trench structure. The trench 38 extends along an outer portion of the semiconductor device and may form a closed perimeter around an inner portion of the semiconductor device. While FIGS. 2-7 and 9-10 illustrate implementations of second edge seals on a single side of various semiconductor devices, it is understood that FIGS. 2-7 and 9-10 illustrate only a portion of the semiconductor devices and the second edge seal may therefore form a closed perimeter around an active area of the semiconductor device. In other implementations, the trench 38 may not form a fully closed perimeter along an outer portion of the semiconductor device but may extend only along a portion of the outer portion of the semiconductor device. In various implementations like the one illustrated in FIG. 2, the trench 38 forming the second edge seal was simultaneously formed with the TSV 30. In other implementations, however, the trench forming the second edge seal may be formed before or after the formation of the TSV.

In various implementations, the trench forming the second edge seal may include a moisture barrier 42 coating the sidewalls of the trench. In various implementations, the moisture barrier 42 may also coat the bottom of the trench which is in contact with the first metal layer 34. In particular implementations, the moisture barrier 42 may include a silicon nitride material or any other nitride material. In other implementations, the moisture barrier may include any other moisture resistant material. In various implementations, the moisture barrier may also coat the sidewalls of the TSV.

In various implementations, the trench may include an encapsulant 44 filling the interior of the trench 38. In such implementations, the moisture barrier 42 is formed between the sidewalls of the trench 38 and the encapsulant 44. As illustrated in FIG. 2, the encapsulant 44 may also be deposited within the TSV 30 and may coat the sidewalls of the moisture barrier 46 material within the TSV 30. In such implementations, the encapsulant 44 within the TSV 44 includes an opening therethrough allowing for the electrically conductive material to be deposited therein to allow for electrical connections to the bond pad 32. The encapsulant 44 may be the same encapsulant used to encapsulate an outer surface of the semiconductor device. In such implementations, the encapsulant may at least partially extend over a first side of the semiconductor device as illustrated in FIG. 2. The encapsulant 44 may also be continuously formed/present between the portion of the encapsulant within the trench 38 forming the second edge seal and the portion of the encapsulant 44 within the TSV 32. In implementations having an image sensor, the encapsulant may cover a light block layer 46 coupled over the image sensor die/first die 26.

In other implementations, rather than or in addition to being filled with the encapsulant, the trench forming the second edge seal may be filled/include with a light block material/layer. In particular implementations the light block material may include a tungsten layer. In other implementations the light block material may include any other optically opaque material configured to block a desired wavelength of light. In implementations including a light block layer, the performance of an image sensor within the semiconductor device may be enhanced due to the reduction of internally reflected/refracted light on the pixel array.

In other implementations, the second edge seal 38 may not include a moisture barrier 42 lining the sidewalls of the trench and may only include the encapsulant 44 filling the trench. In such implementations, the encapsulant 44 acts as a moisture barrier. In still other implementations, the moisture barrier material may fill the entire trench 38. In such implementations, the TSV 30 may not include an encapsulant therein but just the moisture barrier.

In various implementations, the second edge seal 38 of FIG. 2 works to prevent cracks from propagating into the active area of the semiconductor device by forming a solid embedded structure across the various layers of material that form the first and second semiconductor die 26, 28. The second edge seal 38 may also prevent moisture from diffusing into the active areas/other layers of the semiconductor device 24. In various implementations, the second edge seal 38 isolates the bond pad 32 and prevents cracks and moisture from spreading to/into the bond pad region. In turn, those electrical connections made to the bond pad may have enhanced reliability due to the second edge seal 38.

The implementation of a semiconductor die 24 illustrated in FIG. 2 may be formed using various implementations of a method for forming a semiconductor device. In a particular method implementation, the method includes hybrid bonding the first semiconductor die 26 to the second semiconductor die 28. In various method implementations, this takes place at the time a semiconductor substrate that contains the first semiconductor die 26 is bonded to a semiconductor substrate that contains the second semiconductor die 28. However, in some implementations, the die or groups of die may be bonded after being singulated from the respective semiconductor substrates. The method also includes forming the TSV/forming the opening corresponding with the TSV 30 entirely through the thickness of the first die 26 and to the bond pad 32 of the second die 28. The method also includes, simultaneous with the forming of the TSV, forming trench 38 entirely through the thickness of the first die 26 and into the thickness of the second die 28 where the depths into the thickness of the second die 28 is the same as a depth the TSV 30 extends into the thickness of the second die 28. This trench 38 then forms the edge seal.

Various method implementations may further include singulating the first die 26 and the second die 28 and where the simultaneous forming of the trench 38 includes forming the trench 38 between the outer edge 40 of the semiconductor device 24 and a second edge seal (first edge seal 36 illustrated in FIG. 2) formed in a thickness of the first die 26. The method may also include forming the trench 38 between the TSV 30 and the second edge seal (first edge seal 36 illustrated in FIG. 2). The method may include forming a silicon nitride layer on sidewalls of the trench 38. The method may include forming applying an encapsulant to sidewalls of the trench 38 and the sidewalls of the TSV 30. The method may also include forming a light block layer on the sidewalls of the trench 38 and forming a silicon nitride layer on the sidewalls of the trench 38. Many possible methods of forming a semiconductor device may be constructed using the principles disclosed herein.

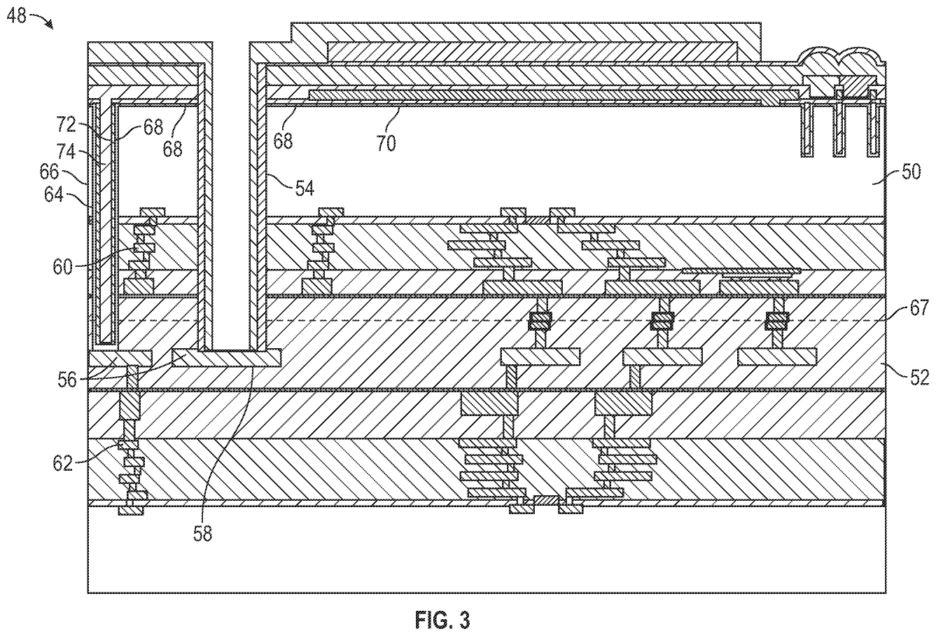

Referring to FIG. 3, a cross-sectional side view of another implementation of a semiconductor device 48 is illustrated. The semiconductor device 48 of FIG. 3 may be any type of semiconductor device disclosed herein. As illustrated by FIG. 3, the semiconductor device includes a first die 50 which may be any type of die disclosed herein. The semiconductor device may also include a second die 52 which may be the same as any die disclosed herein and the relationship between the first and second die 50, 52, including the bond there between, may be the same as or similar to the structural relationship and bond types between the first die and the second die of FIG. 2.

Still referring to FIG. 3, the semiconductor device 48 includes a TSV 54. The TSV 54, including any materials within the TSV, may be the same as or similar to any other TSV disclosed herein. In various implementations, the second die 52 may include a first metal layer 56 which may be the same as or similar to the first metal layer of the implementations discussed relative to FIG. 2. In such implementations, the TSV 54 extends to a bond pad 58 within the first metal layer. In various implementations, the semiconductor device includes a first edge seal 60 in the first die 50 and a first edge seal 62 in the second die 52. The first edge seal may be the same as or similar to the first edge seal of FIG. 2.

Still referring to FIG. 3, in various implementations the semiconductor device includes a second edge seal 64. The second edge seal 64 of FIG. 3 is between the first edge seal 60 and an outer sidewall 66 of the semiconductor device 48. As illustrated by FIG. 3, in various implementations, the second edge seal 64 extends to a same depth within the material/thickness of the second semiconductor die 52 as the TSV 54. In other implementations, the second edge seal 64 may extend within the semiconductor device 48 to a greater depth or lesser depth into the thickness of the semiconductor die 52 than the TSV 54. In particular implementations, the second edge seal 64 extends to the first metal layer 56 and across the bond interface of hybrid bond 67. In other implementations the second edge seal may extend across the bond interface of the hybrid bond 67 between the first and second die 50, 52 but may not necessarily extend to the first metal layer 56 of the second die 52.

In various implementations, the second edge seal 64 includes a trench. The trench 64 may extend along an outer portion of the semiconductor device 48 and may form a closed perimeter around an inner portion of the semiconductor device 48. In other implementations, the trench 64 may not form a closed perimeter along an outer portion of the semiconductor device but may extend only along a portion of the outer portion of the semiconductor device. In the implementation illustrated in FIG. 3, the trench 64 forming the second edge seal is formed prior to the formation of the TSV 54. In particular implementations, and as illustrated by FIG. 3, the trench 64 forming the second edge seal may be formed through the first die 50 and into the thickness of the second die 52 prior to the deposition of a high-k dielectric layer, silicon dioxide layer, or any other layer over the first die 50.

In various implementations, the trench forming the second edge seal may include a high-k dielectric layer 68 coating the sidewalls of the trench 64. In such implementations, the high-k dielectric layer 68 may also be coupled over a first side 70 of the first die opposite to the second side of the first die 50, where the second side is bonded to the second die 52. The high-k dielectric layer 68 may include, by non-limiting example, hafnium oxide (HfO), hafnium oxide and aluminum oxide (HfO—AlO_{X}), tantalum oxide (Ta₂O₅), or any other high-k dielectric compound or material.

In various implementations, the trench forming the second edge seal 64 may include a layer of nitride material 72 directly coupled to the layer of high-k dielectric material 68. In such implementations, the high-k dielectric material 68 may be coupled between the nitride layer 72 and the sidewalls of the trench 64. In other implementations of the second edge seal which do not include a high-k dielectric material, the nitride layer 72 may be directly coupled to and line the sidewalls of the trench 64. The nitride layer 72 serves as a moisture barrier within the second edge seal. In other implementations, however, any other moisture resistant material may be used in place of the nitride layer.

Though not illustrated in FIG. 3, in various implementations the second edge seal may include a light block material formed therein similar to that described with respect to the implementation of FIG. 2. The light block material may be the same as or similar to any light block material disclosed herein. The light block material may completely fill a central portion of the second edge seal or may only coat the nitride layer (or be located between the nitride layer and the high-k dielectric material or the sidewalls of the trench 64). In implementations including a light block layer, the performance of an image sensor within the semiconductor device may be enhanced through reduction of reflected/refracted light contacting the pixel array.

In various implementations, the trench 64 forming the second edge seal may be filled with a passivation/interlayer dielectric material 74 which may also be coupled over the high-k dielectric layer 68. In particular implementations, the passivation layer 74 may include silicon dioxide. In other implementations the trench may be filled with another material coupled over the high-k dielectric layer including a nitride material or a light block material. While the second edge seal 64 of FIG. 3 is illustrated as including a high-k dielectric layer 68, a moisture barrier layer 72, and a passivation layer 74 of silicon dioxide, it is understood that in other implementations the second edge seal may include only one of these layers, only two of these layers, or different and/or additional materials and/or layers capable of forming an edge seal.

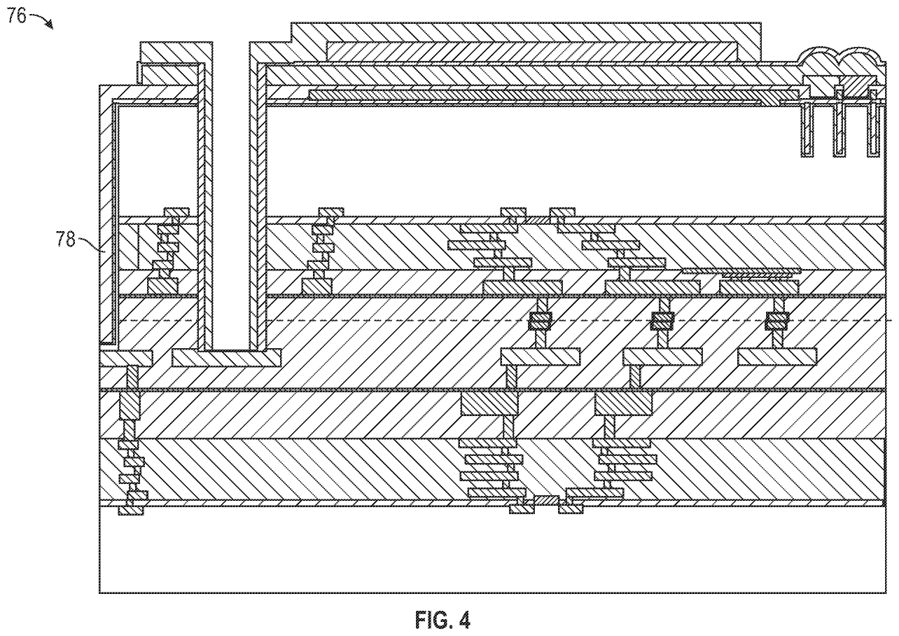

Referring to FIG. 4, a cross-sectional view of another implementation of a semiconductor device 76 is illustrated. The semiconductor device of FIG. 4 is similar to the semiconductor device of FIG. 3 with the difference being that the saw street is set to run through a portion of the second edge seal 78. In turn, the semiconductor device of FIG. 4 is singulated by cutting (or otherwise removing material) through the second edge seal 78. The resulting semiconductor device is accordingly the same as the semiconductor device of FIG. 3 with the difference being that an interior of the trench forming the second edge seal 78 forms a portion of the outer sidewall of the semiconductor device. In implementations where an interior of the trench forming the second edge seal is singulated through, the trench forming the edge seal may be formed wider than the trench illustrated in FIG. 3 in order to provide sufficient room/process margin to ensure singulation through the trench forming the edge seal. In various implementations, metrology structures and test structures may be placed in a single die during the formation of the semiconductor device of FIG. 4.

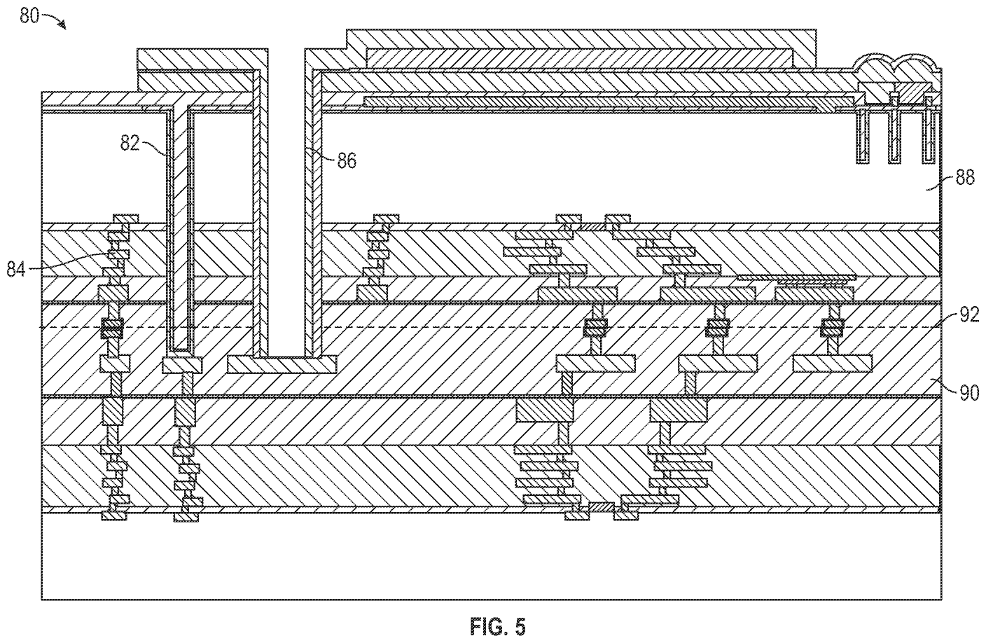

Referring to FIG. 5, a cross-sectional side view of another implementation of a semiconductor device 80 is illustrated. The semiconductor device 80 of FIG. 5 is similar to the semiconductor device 48 of FIG. 3 with the difference being that the second edge seal 82 is located between the first edge seal 84 and the TSV 86. In this implementation, as illustrated in FIG. 5, The first edge seal 84 of the device may extend across the bond between the first die 88 and the second die 90 by being present in both the first die 88 and in the second die 90 and bonded through the hybrid bond 92 (as illustrated by FIG. 5) or may only be present within the first die as illustrated in the implementation of FIG. 3.

In various implementations, the second edge seal implementations illustrated in FIGS. 3-5 cover the entire vertical surface of the first die, crossing the bond interface between the first die, and extending into the material of the second die. In this way, the second edge seal works to prevent cracks from propagating into the active area of the semiconductor device. The second edge seal may also prevent moisture from diffusing into the active area of the semiconductor device. In various implementations, the second edge seal may isolate the bond pad and prevent cracks and moisture from spreading to the bond pad. In turn, the absence of cracks and/or corrosion may allow the electrical connections made to the bond pad to have enhanced reliability due to the second edge seal.

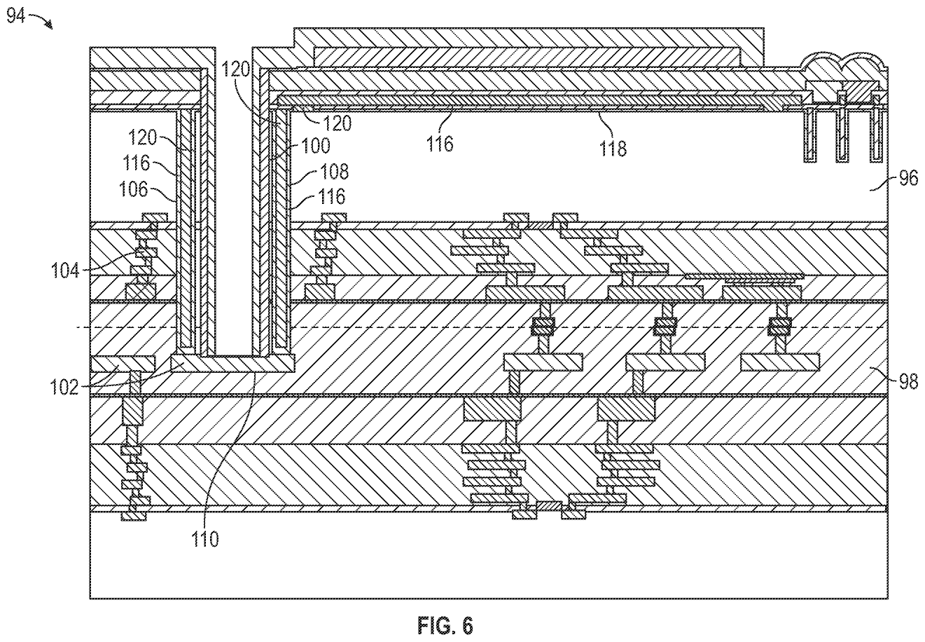

Referring to FIG. 6, a cross-sectional side view of another implementation of a semiconductor device 94 is illustrated. The semiconductor device 94 of FIG. 6 may be any type of semiconductor device disclosed herein. As illustrated by FIG. 6, the semiconductor device includes a first die 96 which may be any type of die disclosed herein. The semiconductor device also includes a second die 98 which may be the same as any die disclosed herein and the relationship between the first and second die, including the bond there between, may be the same as or similar to the structural relationship between the first die and the second die illustrated in FIG. 2.

The implementations of semiconductor devices illustrated in FIGS. 3-5 may be formed using various implementations of a method of forming a semiconductor device. An implementation of a method of forming a semiconductor device includes hybrid bonding a first semiconductor die to a second semiconductor die using any method and process disclosed herein. The method also includes forming a trench entirely through the thickness of the first semiconductor die where the trench extends into the material/thickness of the second die to a first depth. The method also includes after forming the trench, forming a TSV extending entirely through the thickness of the first semiconductor die and to a bond pad included in the second semiconductor die at the first depth where the trench forms an edge seal. Here the trench may be formed during initial processing of a back side integrated (BSI) sensor while forming the various pixel structures therein including any deep trench isolation structures, color filter array, microlenses, etc. In particular implementations, the trench may be formed along with deep trench isolation structures, either simultaneously or just prior or just after.

The method may also include singulating the first semiconductor die and the second semiconductor die where forming the trench also includes forming the trench between an outer edge of the semiconductor device and a second edge seal formed in the thickness of the first semiconductor die. The method may also include where forming the TSV further includes forming the TSV so the trench is between the TSV and a second edge seal (first edge seal in FIGS. 3-5) formed in the thickness of the first semiconductor die. The method may further include filling the trench with silicon nitride. The method may also include forming a light block layer on the sidewalls of the trench and forming a silicon nitride layer on the sidewalls of the trench. The method may also include filling the trench with silicon dioxide. Those of ordinary skill will readily appreciate how to construct many method implementations using the principles disclosed herein.

As illustrated in FIG. 6, the semiconductor device 94 includes a TSV 100. The TSV 100, including any materials within the TSV, may be the same as or similar to any other TSV disclosed herein. In various implementations, the second die 98 includes a first metal layer 102 which may be the same as or similar to the first metal layer of FIG. 2. In such implementations, the TSV extends to a bond pad 110 within the first metal layer 102.

In various implementations, the semiconductor device 94 may include a first edge seal 104. The first edge seal 104 may be the same as or similar to the first edge seal of FIG. 2.

Still referring to FIG. 6, in various implementations the semiconductor device 94 includes a second edge seal in the form of two openings 106, 108 on each side of the TSV 100. As illustrated, one of the openings 106 of the second edge seal is between the first edge seal 104 and the TSV 100. As illustrated by FIG. 6, in various implementations the two openings 106, 108 second edge seal extend to bond pad 110 exposed by the TSV 100.

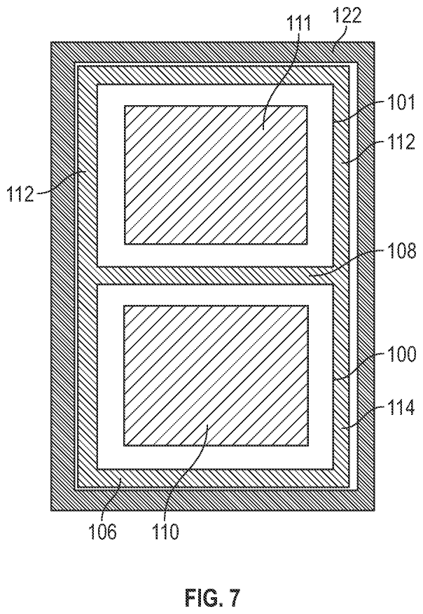

Referring to FIG. 7, a top view of the second edge seal 112 and bond pads 110, 111 of FIG. 6 is illustrated. The second edge seal 112 includes a trench 114 formed of the two openings 106, 108 which are portions of the trench 144 that is illustrated as extending around each of the bond pads 110, 111. As illustrated by FIGS. 6-7, the trench 114 may extend along an outer portion of each bond pad 110, 111 and forms a closed perimeter around the TSVs 100, 101 that expose each bond pad 110, 111. In various implementations, and as illustrated by FIG. 7, the second edge seal 112 may form a closed perimeter around a first bond pad 110 and may also form another closed perimeter around a second bond pad 111. In such implementations, the portion of the second edge seal 112 between the first bond pad 110 and the second bond pad 111 may partially isolate both the first bond pad 110 and the second bond pad 111. In other implementations, the trench 114 may not form a closed perimeter along an outer portion of the bond pad but the openings that form the trench may extend only along a portion(s) of the outer portion of the bond pad(s) 110, 111. In various implementations, the trench 114 forming the second edge seal 112 may be formed prior to the formation of the TSVs 100, 101. In particular implementations, and as illustrated by FIG. 6, the trench 114 forming the second edge seal 112 may be formed through the first die 96 and into the second die 98 prior to the deposition of a high-k dielectric layer, or any other layer over the first die. In various implementations, the formation may be done during process of a back side integrated portions of the image sensor device similar to the implementations of FIGS. 3-5 using any of the method implementations disclosed previously.

In various implementations as illustrated in FIGS. 6 and 7, the trench 114 forming the second edge seal 112 may include a high-k dielectric layer 116 coating the sidewalls of the trench. In such implementations the high-k dielectric layer 116 may also be coupled over a first side 118 of the first die 96 opposite to the second side of the first die 96, which second side is bonded to the second die 98. The high-k dielectric layer 116 may include any type of high-k dielectric material disclosed herein.

In various implementations, the trench 114 forming the second edge seal 112 may include a nitride material 120 directly coupled to the high-k dielectric material 116 and filling the remainder of the trench 114 that forms the second edge seal 112. In such implementations, the high-k dielectric material 116 may be coupled between the nitride layer/material 120 and the sidewalls of the trench 114. In other implementations of the second edge seal 112 not including a high-k dielectric material/layer, the nitride layer 120 may be directly coupled to and line the sidewalls of the trench or entirely fill the trench. The nitride layer 120 may serve as a moisture barrier within the second edge seal 112. In other implementations, any other moisture resistant material may be used in place of the nitride.

Though not illustrated by FIG. 6, in various implementations the second edge seal may include a light block material formed therein. The light block material may be the same as or similar to any light block material disclosed herein. In various implementations the light block material may completely fill a central portion of the second edge seal or may coat sidewalls of the trench forming the second edge seal. In implementations including a light block layer, the performance of an image sensor within the semiconductor device may be enhanced through reduction of reflection/refracted light into the pixel portion of the image sensor.

Still referring to FIGS. 6-7, in various implementations the semiconductor device may include a grid 122 that further seals the TSVs 100, 101. In various implementations, the grid 122 surrounds the TSV 100, 101 and extends downwardly to the surface of the bond pads 110, 111. In implementations having multiple bond pads and multiple TSVs, the grid 122 may surround multiple bond pads as illustrated in FIG. 7. In other implementations the grid 122 may surround a single bond pad, three bond pads, four bond pads, or more than four bond pads. The grid may be made from, by non-limiting example, tungsten, any other light block material, or any other type of material capable of forming a seal. In various implementations, the grid 122 may be formed over the first die 96 and within a silicon dioxide layer. In such implementations, a via may be formed next to the second edge seal and through the passivation layer (which may be the silicon dioxide layer) to the first die. In implementations of semiconductor devices including a high-k dielectric layer formed over the first die, the via may be formed through the high-k dielectric layer. The grid may fill the via and extend to the first die next to the second edge seal. In turn, the grid may further seal the TSV.

In various implementations, the second edge seal 112 of FIG. 6 may cover the entire thickness of the first die 96 across the bond interface of the hybrid bond between the first die 96 and the second die 98. In turn, the second edge seal 112 may electrically isolate the bond pad and any electrical connections made thereto through filling/coating the TSV 100 with an electrically conductive material. Further, the second edge seal 112 may prevent cracks from propagating into the bond pad area and may also prevent moisture from diffusing into the bond pad area. In turn, the electrical connections made to the bond pad may have enhanced reliability due to the second edge seal.

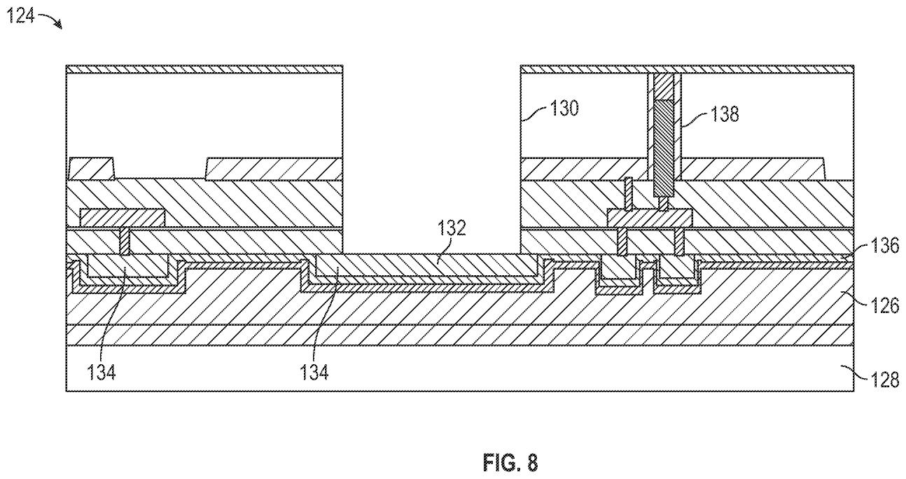

Referring to FIG. 8, a cross-sectional side view of another implementation of a semiconductor device 124 is illustrated. In various implementations, and as illustrated by FIG. 8, the semiconductor device 124 is a backside illuminated (BSI) semiconductor device and the first die 126 may include a BSI image sensor. In particular implementations, the semiconductor device may be a silicon photomultiplier BSI semiconductor device. In other implementations, the first die 126 may be a different type of semiconductor device.

In various implementations, the first die 126 includes a through-silicon-via (TSV) 130 extending into the thickness of the first die 130 of the semiconductor device. As illustrated by FIG. 8, the TSV 130 extends to bond pad 132 within the first die 130 and enables, when filled with or layered with an electrically conductive material, an electrical connection to be established through the TSV 130 and to the bond pad 132. The bond pad 132 may be part of a second metal layer 134 within the first die 126.

In various implementations the semiconductor device 124 includes passivation layer 136. The passivation layer 136 illustrated is coupled between the second metal layer and an internal circuit region below the second metal layer and extend to an outer edge of the semiconductor device. The passivation layer 136 in various implementations may include silicon dioxide or any other type of passivation material.

Still referring to FIG. 8, the semiconductor device 124 includes an edge seal 138. In various implementations, the edge seal 138 includes a plurality of stacked metal layers coupled together through vias. In various implementations the edge seal 138 is formed in the first die 126. In various implementations, as illustrated in FIG. 8, the edge seal extends to and terminates at the second metal layer 134.

In various implementations, moisture may diffuse through the passivation layer 136 to the second metal layer 133 and result in corrosion of the material of second metal layer which can cause reliability and other issues.

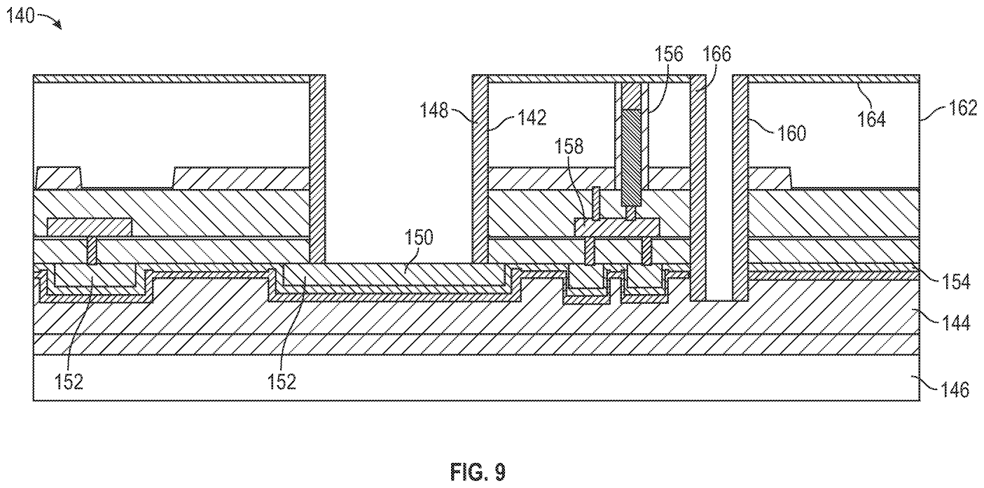

Referring to FIG. 9, a cross-sectional side view of another implementation of a semiconductor device 140 is illustrated. The semiconductor device may be a backside illuminated (BSI) semiconductor device. In particular implementations, the semiconductor device may be a silicon photomultiplier BSI semiconductor device or any other disclosed in this document.

As illustrated, the semiconductor device 140 includes a TSV 142 extending into the thickness of a first die 144 of the semiconductor device. The TSV 142 includes a nitride layer 148 coupled to the sidewalls of the TSV 142. In particular implementations, the nitride layer 148 may be silicon nitride. As illustrated by FIG. 9, the TSV 142 extends to bond pad 150 within the first die 144 and an electrical connection is established through the TSV 142 when the TSV 142 is subsequently filled/layered with an electrically conductive material in contact with the bond pad 150. The bond pad 150 is part of a second metal layer 152 within the first die 144. As illustrated in FIG. 9, the semiconductor device 144 includes passivation layer 154. The passivation layer 154 is coupled between the second metal layer 152 and an internal circuit region below the second metal layer 152 and may extend to an outer edge of the semiconductor device 140 when the device is singulated.

Still referring to FIG. 9, the semiconductor device includes a first edge seal 156. In various implementations, the first edge seal 156 includes a plurality of stacked metal layers coupled together through vias. In various implementations, the first edge seal 156 is formed in the first die 144. The first edge seal 144 is illustrated to extend to the second metal layer 152 in the thickness of the first die 144 using structure of a first metal layer 158 to do so.

FIG. 9 illustrated how this implementation of a semiconductor device 140 includes a second edge seal 160 formed in the thickness of the first die between the first edge seal 156 and an outer sidewall 162 of the semiconductor device 140. In various implementations, the second edge seal 160 includes a trench formed from a backside 164 of the first die 144 into the internal circuit region of the first die 144. In such implementations, the trench 160 forming the second edge seal extends across the passivation layer 154. Various second edge seal implementations include a nitride layer 166 directly coupled to the sidewalls of the trench 160 which extends across the passivation layer 154. In various implementations, the trench 160 forming the second edge seal is formed at the same time as the TSV 142 is. In other implementations, the trench 160 forming the second edge seal may be formed prior to or after the formation of the TSV 142. In particular implementations, the nitride layer 166 coating the second edge seal 160 may be the same material as a nitride layer 148 coating the sidewalls of the TSV 142. In other implementations, a different material, including any material or combination of materials/layers disclosed herein, may line the sidewalls of the trench 160 forming the second edge seal.

In various implementations, though not illustrated by FIG. 9, the second edge seal 160 may be entirely filled. In such implementations, the second edge seal may be filled with the nitride material (which may be silicon nitride) or any other material disclosed herein. However, in the implementation illustrated in FIG. 9, the second edge seal 160 is not entirely filled leaving an air gap.

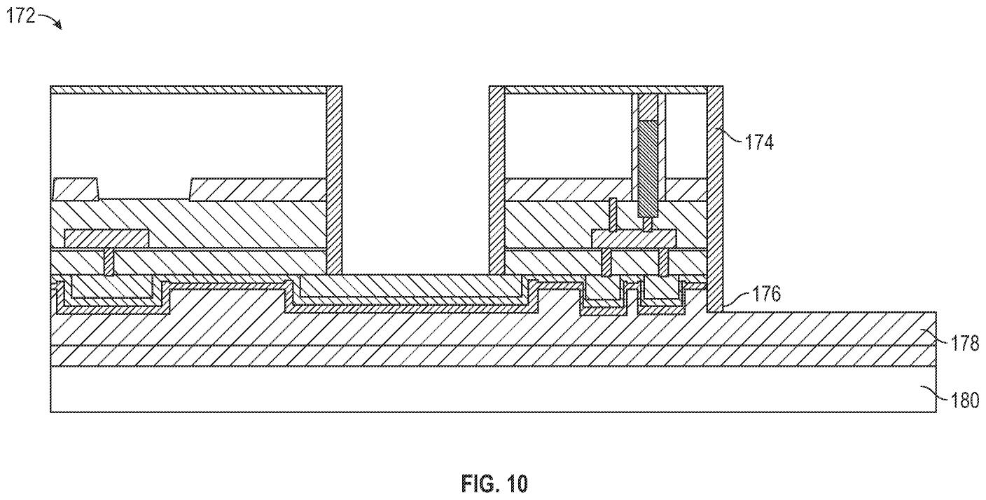

Referring to FIG. 10, a cross-sectional side view of another implementation of a semiconductor device 172 is illustrated. The semiconductor device 172 of FIG. 10 may be similar to the semiconductor device of FIG. 9 with the difference being that a stepped saw street runs through the second edge seal 174 with the first wider kerf saw cut cutting into the second edge seal. The second narrower kerf saw cut then completes the singulation process leaving a stepped cut. The resulting semiconductor device 172 is accordingly the same as the semiconductor device of FIG. 9 with the difference being that an interior of the trench forming the second edge seal 174 forms a portion of the outer sidewall 176 of the semiconductor device 172. In implementations where an interior of the trench forming the second edge seal is singulated through, and as illustrated by FIG. 10, the trench forming the edge seal may be formed with a width wider than a width of the trench of FIG. 9 in order to provide sufficient room to singulate through the trench forming the second edge seal 174. In various implementations, metrology structures and test structures may be placed in a single die during the formation of the semiconductor device of FIG. 10.

In various implementations, the second edge seals 160, 174 of FIGS. 9-10 may extend from the backside of the first die 144, 178 across the passivation layer and beyond the second metal layer into the second die 146, 180. In turn, the second edge seals 160, 174 may prevent cracks from propagating into the semiconductor device and may also prevent moisture from diffusing to the second metal layer causing corrosion to form. In turn, the electrical connections made to the bond pad may have enhanced reliability due to these effects provided by the second edge seals 160, 174.

While the implementations of FIGS. 2-7 and 9-10 all illustrate a first edge seal, in other implementations it is understood that the semiconductor devices of FIGS. 2-7 and 9-10 may not include the first edge seal and may only include the structure what is illustrated as the second edge seal of FIGS. 2-7 and 9-10 and a single edge seal (or multiple seals of the same structure as presented in the implementation of FIGS. 6-7.

In places where the description above refers to particular implementations of edge seals for semiconductor devices and implementing components, sub-components, methods and sub-methods, it should be readily apparent that a number of modifications may be made without departing from the spirit thereof and that these implementations, implementing components, sub-components, methods and sub-methods may be applied to other edge seals for semiconductor devices.

What is claimed is:

1. A semiconductor device comprising:
a first semiconductor die hybrid bonded to a second semiconductor die;
a bond pad comprised in the second semiconductor die;
a through-silicon-via (TSV) extending entirely through the first semiconductor die and to the bond pad comprised in the second semiconductor die;
a trench formed entirely through the first semiconductor die and to the bond pad comprised in the second semiconductor die;
wherein the trench forms an edge seal.

2. The semiconductor device of claim 1, wherein the trench surrounds the TSV and the bond pad.

3. The semiconductor device of claim 1, further comprising a tungsten grid at least partially overlapping the trench.

4. The semiconductor device of claim 1, wherein a nitride material fills the trench.

5. The semiconductor device of claim 4, further comprising a light block material comprised in the trench.

6. The semiconductor device of claim 5, wherein the light block layer extends over a first side of the first semiconductor die.

7. The semiconductor device of claim 1, further comprising a nitride layer coupled over a plurality of sidewalls of the TSV and an encapsulant coupled over sidewalls of the nitride layer.

8. The semiconductor device of claim 1, wherein the trench is present on at least two sides of the TSV.

9. A method of forming a semiconductor device comprising:
hybrid bonding a first semiconductor die to a second semiconductor die;
forming a through-silicon-via (TSV) extending entirely through a thickness of the first semiconductor die and to a bond pad comprised in the second semiconductor die; and
simultaneously forming a trench entirely through the thickness of the first semiconductor die and into the second semiconductor die, wherein the trench extends into the second die to a same depth into a thickness of the second semiconductor die as a depth the TSV extends into the thickness of the second semiconductor die;
wherein the trench forms an edge seal.

10. The method of claim 9, further comprising singulating the first semiconductor die and the second semiconductor die and wherein simultaneously forming a trench further comprises forming the trench between an outer edge of the semiconductor device and a second edge seal formed in the thickness of the first semiconductor die.

11. The method of claim 9, wherein simultaneously forming a trench further comprises forming the trench between the TSV and a second edge seal formed in the thickness of the first semiconductor die.

12. The method of claim 9, further comprising forming a silicon nitride layer on sidewalls of the trench.

13. The method of claim 9, further comprising applying an encapsulant to sidewalls of the trench and sidewalls of the TSV.

14. The method of claim 9, further comprising:
forming a light block layer on sidewalls of the trench; and
forming a silicon nitride layer on the sidewalls of the trench.

15. A method of forming a semiconductor device comprising:
hybrid bonding a first semiconductor die to a second semiconductor die;
forming a trench entirely through a thickness of the first semiconductor die and into the second semiconductor die, wherein the trench extends into the second die to a first depth;
after forming the trench, forming a through-silicon-via (TSV) extending entirely through a thickness of the first semiconductor die and to a bond pad comprised in the second semiconductor die at the first depth; and
wherein the trench forms an edge seal.

16. The method of claim 15, further comprising singulating the first semiconductor die and the second semiconductor die and wherein forming the trench further comprises forming the trench between an outer edge of the semiconductor device and a second edge seal formed in the thickness of the first semiconductor die.

17. The method of claim 15 wherein forming the TSV further comprises forming the TSV so the trench is between the TSV and a second edge seal formed in the thickness of the first semiconductor die.

18. The method of claim 15, further comprising filling the trench with silicon nitride.

19. The method of claim 15, further comprising:
forming a light block layer on sidewalls of the trench; and
forming a silicon nitride layer on the sidewalls of the trench.

20. The method of claim 19, further comprising filling the trench with silicon dioxide.
